(19) United States
(12) Patent Application Publication
(10) Pub. No.: US 2025/0127023 A1
(43) Pub. Date: Apr. 17, 2025

(54) DISPLAY APPARATUS

(71) Applicant: LG Display Co., Ltd., Seoul (KR)

(72) Inventors: Hyun KIM, Paju-si (KR); Sang-Mo BYUN, Paju-si (KR); Da-Yeon JEONG, Paju-si (KR)

(73) Assignee: LG Display Co., Ltd., Seoul (KR)

(21) Appl. No.: 18/909,376

(22) Filed: Oct. 8, 2024

(30) Foreign Application Priority Data
Oct. 17, 2023 (KR) 10-2023-0138713

(51) Int. Cl. H10K 59/80

(52) U.S. Cl. CPC H10K 59/8791; H10K 59/873

(57) ABSTRACT

A display apparatus in one example includes a substrate having a display area and a non-display area, a plurality of transistors and a light emitting device disposed in the display area, an encapsulation layer disposed in the display area and the non-display area, and a reflective member disposed in the non-display area to surround the display area. The reflective member includes a retroreflective to reflective light incident from outside to observe flow of the encapsulating layer.

### CROSS-REFERENCE TO RELATED APPLICATIONS

This application claims priority to Korean Patent Application No. 10-2023-0138713, filed in the Republic of Korea on Oct. 17, 2023, the entire contents of which is hereby expressly incorporated by reference into the present application.

### BACKGROUND

### Field of the Disclosure

The present disclosure relates to a display apparatus, and more particularly, for example, without limitation, to a display apparatus that can minimize a bezel size of the display apparatus.

### Description of the Background

Recently, a wide use of a display apparatus has increased with the development of multimedia. Various display apparatuses, such as a liquid crystal display and an organic light emitting displays, have been developed and used.

As the display apparatuses are applied to small portable electronic devices such as smartphones and tablet PCs, the bezel area of the display apparatus needs to be minimized or eliminated to achieve a relatively large screen even in small area display apparatuses and to have an attractive appearance.

The description provided in the discussion of the related art section should not be assumed to be prior art merely because it is mentioned in or associated with that section. The discussion of the related art section can include information that describes one or more aspects of the subject technology, and the description in this section does not limit the disclosure.

### SUMMARY OF THE DISCLOSURE

An object of the present disclosure is to provide a display apparatus including a retroreflective member to observe a flow of an organic material for an encapsulating layer in order to minimize the number of the dam for blocking the flow of the organic material and reduce the area of a bezel.

Purposes according to the present disclosure are not limited to the above-mentioned purposes. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

In order to achieve these objects, a display apparatus according to one or more aspects of the present disclosure comprises a substrate including a display area and a non-display area; a plurality of transistors and light emitting device disposed in the display area; an encapsulation layer disposed in the display area and the non-display area; and a reflective member disposed in the non-display area to surround the display area, wherein the reflective member includes a retroreflective layer to reflective light incident from outside to observe flow of the encapsulating layer.

According to one or more aspects of the present disclosure, the reflective member can include a metal layer of a three dimensional concavo-convex shape on the gate insulating layer. The gate insulating layer can be etched in the three dimensional protrusion shape and the reflective member can be disposed on the surface of the gate insulating layer. The reflective member can include a plurality of protruding insulating layers disposed on the gate insulating layer and a metal layer on the plurality of protruding insulating layers.

According to one or more aspects of the present disclosure, the reflective member can be a metal layer of the three dimensional concavo-convex shape on the interlayer insulating layer. The surface of the interlayer insulating layer can be etched in the three dimensional protruding shape and the reflective member can be the metal layer disposed on the surface of the interlayer insulating layer. The reflective member can include a plurality of protruding insulating layers disposed on the interlayer insulating layer and a metal layer disposed on the plurality of protruding insulating layers.

According to one or more aspects of the present disclosure, the metal layer can be disposed of the metal have getter characteristics.

It is to be understood that both the foregoing general description and the following detailed description of the present disclosure are example and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic block diagram of an organic light emitting display apparatus according to aspects of the present disclosure.

FIG. 2 is a schematic block diagram of an organic light emitting display apparatus according to aspects of the present disclosure.

FIG. 3 is the circuit diagram conceptually showing the sub-pixel of the display apparatus according to aspects of the present disclosure.

FIG. 4 is a plan view of the display apparatus according to aspects of the present disclosure.

FIG. 5 is a cross-sectional view of the display apparatus according to a first example embodiment of the present disclosure.

FIG. 6A is a view showing a method of determining the location of the encapsulation layer when a reflective member made of a mirror shaped reflective layer is formed.

FIG. 6B is a view showing the method for determining the location of the encapsulation layer when the reflective member made of a retroreflective layer is formed according to the first example embodiment of the present disclosure.

FIG. 7A is a view showing a reflected image taken when the reflective member made of the mirror-shaped reflective layer is formed.

FIG. 7B is a view showing the reflected image taken when the reflective member made of the retroreflective layer is formed.

FIG. 8 is an enlarged cross-sectional view of the reflective member of FIG. 5.

FIG. 9A is an enlarged perspective view specifically showing the structure of the retroreflective layer according to the first example embodiment of the present disclosure.

FIG. 9B is a view showing one corner reflecting mirror of the retroreflective layer of FIG. 9A.

FIGS. 10A and 10B are views showing different structures of the reflective member of the display apparatus according to the first example embodiment of the present disclosure.

FIG. 11 is a cross-sectional view of a display apparatus according to a second example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the disclosure and can be thus different from those used in actual products.

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes (e.g., sizes, lengths, widths, heights, thicknesses, locations, radii, diameters, and areas), ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted or briefly given herein. When terms such as “including,” “having,” “comprising,” “contain,” “constitute,” “make up of,” “formed of,” and the like mentioned in this disclosure are used, other parts can be added unless the term “only” is used herein. When a component is expressed as being singular, being plural is included unless otherwise specified.

The word “exemplary” is used to mean serving as an example or illustration. Aspects are example aspects. Further, “embodiments,” “examples,” “aspects,” and the like should not be construed as preferred or advantageous over other implementations. An embodiment, an example, an example embodiment, an aspect, or the like can refer to one or more embodiments, one or more examples, one or more example embodiments, one or more aspects, or the like, unless stated otherwise. Further, the term “can” encompasses all the meanings of the term “may.”

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts can be located between the two parts. For example, where an element or layer is disposed “on” another element or layer, a third layer or element can be interposed therebetween.

The terms, such as “below,” “lower,” “above,” “upper” and the like, can be used herein to describe a relationship between element(s) or item(s) as illustrated in the drawings. It will be understood that the terms are spatially relative and based on the orientation depicted in the drawings.

In describing a temporal relationship, for example, when a temporal predecessor relationship is described as being “after,” “subsequent,” “next to,” “prior to,” or the like, unless “immediately” or “directly” is used, cases that are not continuous can also be included.

Although the terms first, second, and the like are used to describe various components, these components are not substantially limited by these terms. These terms are used only to distinguish one component from another component, and may not define order or sequence. Therefore, a first component described below can substantially be a second component within the technical spirit of the present disclosure.

In describing the components of the invention, terms such as first, second, A, B, (a), (b), etc. can be used. These terms are only for distinguishing the elements from other elements, and the essence, order, or number of the elements are not limited by the terms. When it is described that a component is “coupled” or “connected” to another component, the component can be directly coupled or connected to the other component, but indirectly without specifically stated. It should be understood that other components can be “interposed” between each component that is connected or can be connected.

As used herein, the term “apparatus” can include a display apparatus such as a liquid crystal module (LCM) including a display panel and a driving unit for driving the display panel, and an organic light emitting display module (OLED module). Further, the term “apparatus” can further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module, etc.

Accordingly, the apparatus in the invention can include the display apparatus itself such as the LCM, the OLED module, etc., and the application product including the LCM, the OLED module, or the like, or the set apparatus, which is the apparatus for end users.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

This disclosure can be applied to the various display apparatus. For example, the display apparatus of this disclosure can be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

The features of the various embodiments of the present disclosure can be partially or entirely combined with each other, and can be technically associated with each other or operate with each other. The embodiments can be implemented independently of each other and can be implemented together in an association relationship.

Hereinafter, the present disclosure will be described in detail with reference to the attached drawings. The scales of the components shown in the drawings have different scales from the actual ones for convenience of explanation, and thus are not limited to the scales shown in the drawings. All the components of each display apparatus according to all embodiments of the present disclosure are operatively coupled and configured.

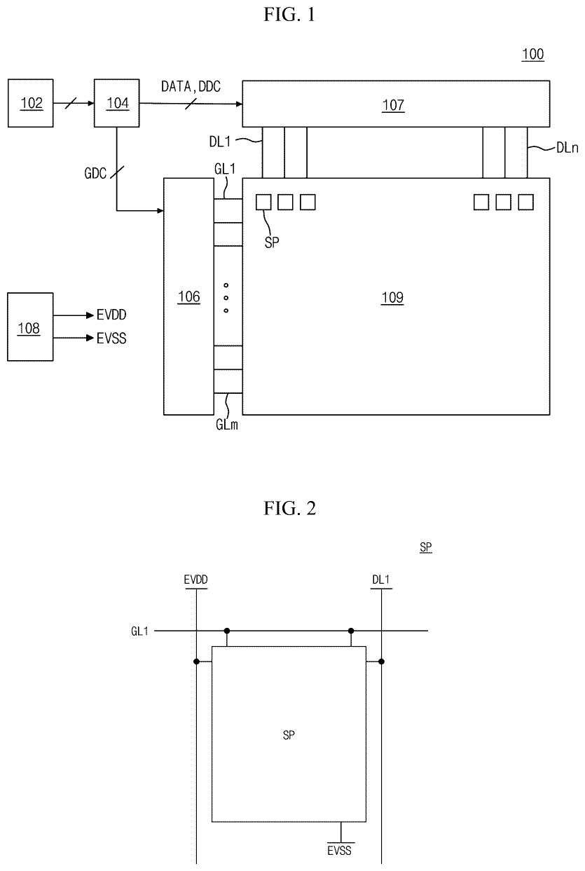

FIG. 1 is the schematic block diagram and FIG. 2 is the schematic block diagram of the sub-pixel of the organic light emitting display apparatus according to aspects of the present disclosure.

As shown in FIG. 1, an organic light emitting display apparatus 100 includes an image processing unit 102, a timing controlling unit 104, a gate driving unit 106, a data driving unit 107, a power supplying unit 108, a display panel 109, and the like.

The image processing unit 102 outputs an image data supplied from outside and a driving signal for driving various devices. For example, the driving signal from the image processing unit 102 can include a data enable signal, a vertical synchronizing signal, a horizontal synchronizing signal, a clock signal, and the like, for example, from an external device such as a host system.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 can be a circuit for driving a plurality of gate lines GL1 to GLm, and can supply scan signals to the plurality of gate lines GL1 to GLm, where m is a real number. The gate driving unit 106 outputs the scan signal through the plurality of gate lines GL1 to GLm. In this case, the gate driving unit 106 can be formed in the form of an integrated circuit (IC), but is not limited thereto. The gate driving unit 106 includes various gate driving circuits, and the gate driving circuits can be directly formed on the substrate. In this case, the gate driving unit 106 can be a gate-in-panel (GIP), but is not limited thereto.

As another example, the gate driving unit 106 can be configured with at least one gate IC. As an example, the gate driving unit 106 can be connected to the display panel 100, for example, in a tape automated bonding (TAB) method, a chip on glass (COG) method, a chip on panel (COP) method, or a chip on film (COF) method, without being limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 can be a circuit for driving the plurality of data lines DL1 to DLn, and can supply data signals to the plurality of data lines DL1 to DLn, where n is a real number. The data driving unit 107 outputs the data voltage through the plurality of data lines DL1 to DLn. In this case, the data driving unit 107 can be mounted on the upper surface of the display panel 109 in the form of an integrated circuit (IC), but is not limited thereto.

The power supplying unit 108 outputs a high potential voltage VDD and a low potential voltage VSS etc., on the basis of an external input voltage supplied from the outside, to supply these to the display panel 109. The high potential voltage VDD is supplied to the display panel 109 through the first power line EVDD and the low potential voltage VSS is supplied to the display panel 109 through the second power line EVSS. In this time, the power supplying unit 108 can generate and output a voltage needed for driving of the gate driving unit 106, a voltage needed for driving of the data driving unit 107, and a voltage needed for driving of a memory, in addition to the high potential voltage VDD and the low potential voltage VSS, for example, the voltage from the power supplying unit 108 are applied to the data driving unit 107 or the gate driving unit 106 to drive thereto.

The display panel 109 displays the image based on the data voltage from the data driving unit 107, the scan signal from the gate driving unit 106, and the power from the power supplying unit 108.

The display panel 109 includes a plurality of sub-pixels SP to display the image. The sub-pixel SP can include Red sub-pixel, Green sub-pixel, and Blue sub-pixel, but is not limited thereto. Further, the sub-pixel SP can include White sub-pixel, the Red sub-pixel, the Green sub-pixel, and the Blue sub-pixel, but is not limited thereto. The White sub-pixel, the Red sub-pixel, the Green sub-pixel, and the Blue sub-pixel can be formed in the same area or can be formed in different areas. Embodiments are not limited thereto. As an example, the sub-pixel SP of other colors such as magenta, cyan, or yellow can be alternatively or additionally included, without being limited thereto. In one or more aspects, the display apparatus can be a liquid crystal display device (LCD), a plasma display device (PDP), a field emission display device (FED), or the like, or a self-emission display device in which light is emitted from the display panel 109 itself, such as an organic light-emitting display device (OLED), and a micro LED (Micro Light Emitting Diode) display device. In the example where the display apparatus is a self-emission display device, each of the plurality of sub-pixels SP can include a light emitting element.

As shown in FIG. 2, each sub-pixel SP can be connected to the gate line GL1, the data line DL1, the first power line EVDD, and the second power line EVSS. The sub-pixel SP can include a plurality of thin film transistors and a storage capacitor depending on the configuration of the pixel circuit. For example, the sub-pixel SP can include two transistors and one capacitor (it is called 2T1C), but is not limited thereto, and can include more or less elements. The sub-pixel SP can be composed of 3T1C, 4T1C, 5T1C, 6T1C, 7T1C, 3T2C, 4T2C, 5T2C, 6T2C, 7T2C, 8T2C, etc.

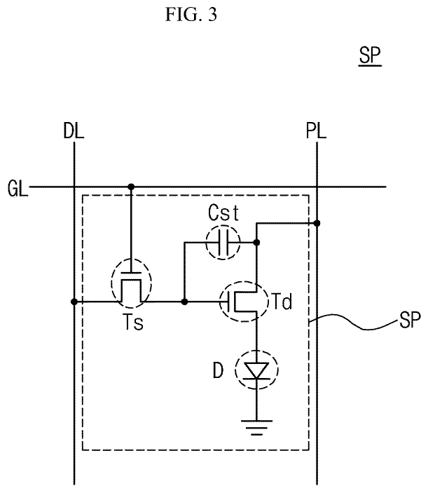

FIG. 3 is the circuit diagram illustrating an example of the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor Td, a storage capacitor Cst, and a light emitting device D are disposed in the sub-pixel SP, and the like.

The switching thin film transistor Ts is connected to the gate line GL and the data line DL, in particular, the gate electrode of the switching thin film transistor Ts is connected to the gate line GL, and the drain electrode of the switching thin film transistor Ts is connected to the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode thereof. As a result, the current proportional to the data signal is supplied to the light emitting device D from the power line PL through the driving thin film transistor Td and then the light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors can be provided in the present disclosure.

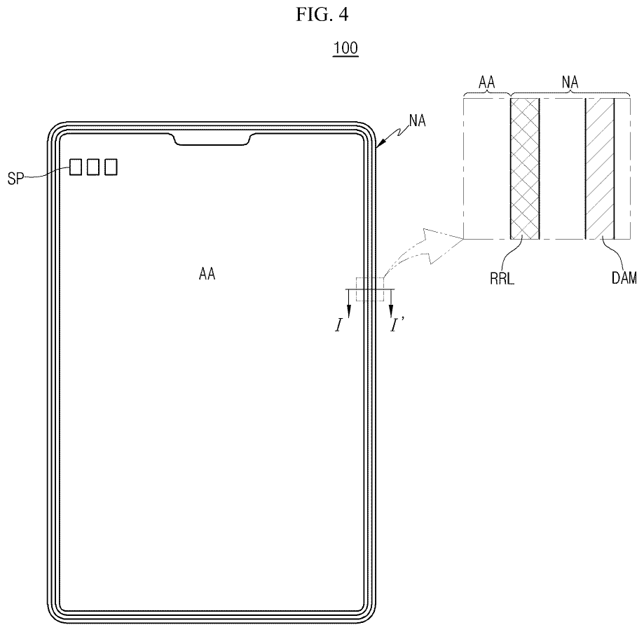

FIG. 4 is the plan view schematically showing the structure of the display apparatus 100 according to the present disclosure.

As shown in FIG. 4, the display apparatus 100 according to the present disclosure includes a display area AA (or active area) for displaying an image and a non-display area NA (or non-active area) disposed outside the display area AA. The non-display area NA can surround the display area AA entirely or only in parts.

The non-display area NA can refer to an area outside of the display area AA. Several types of signal lines can be disposed in the non-display area NA, and several types of driving circuits can be connected thereto. At least a portion of the non-display area NA can be bent to be invisible from the front surface of the display apparatus 100 or can be covered by a case or housing of the display apparatus 100. The non-display area NA can be also referred to as an edge area or a bezel area.

A plurality of pixels P are arranged in the display area AA, and each pixel P includes a plurality of sub-pixels SP. At this time, the sub-pixel SP can be a red (R) sub-pixel, a green (G) sub-pixel, or a blue (B) sub-pixel, without being limited thereto. Further, the sub-pixel SP can be a white (W) sub-pixel. As an example, the sub-pixels SP in each pixel P can be R, G and B sub-pixels, or R, G, B and W sub-pixels.

Further, a plurality of gate lines and data lines are arranged in the display area AA, and the sub-pixel SP is disposed in the intersection area of the gate line and data line. In each sub-pixel SP, a thin film transistor that is a switching element and a display apparatus to display the image are disposed.

The display apparatus can include various display apparatus. For example, the display apparatus can be an organic light emitting display device, a liquid crystal display device, a quantum dot display device, a micro LED display device, or a mini LED display device.

The gate driving and the data driving unit that apply various signals to the sub-pixel SP can be disposed in the non-display area NA. The gate driving unit applies the scan signal to the sub-pixel SP through the gate line, and the data driving unit applies the image signal to the sub-pixel SP through the data line.

A dam DAM surrounding the display area AA is formed in the non-display area NA. When the thin film transistor or the organic light emitting layer of the display apparatus 100 is exposed to external impurities such as air or moisture, the thin film transistor or the organic light emitting layer is deteriorated and the display apparatus 100 is defective. Therefore, an encapsulation layer must be formed in the display apparatus 100 to seal the display apparatus 100 from the external environment. As will be explained later, when applying the encapsulation material to form an encapsulation layer, the dam DAM is formed in the non-display area NA to block the flow of the encapsulation material, thereby preventing the encapsulation material from flowing to the outside of the display apparatus 100. The encapsulation layer can include an inorganic insulating material and/or an organic encapsulation layer. For example, the inorganic encapsulation layer can include an inorganic insulating material capable of low-temperature deposition, such as silicon nitride (SiN), silicon oxide (SiO), silicon oxynitride (SiON) and aluminum oxide (AlO). For example, the organic encapsulation layer can include an organic insulating material, such as acrylic resin, epoxy resin, polyimide, polyethylene and silicon oxycarbide (SiOC).

In a general display apparatus, a plurality of dams DAM are disposed to surround the outside of the display area AA to reliably prevent the encapsulation material from flowing out. The reason for forming multiple dams DAM is as follows.

If the encapsulation layer is not formed in a uniform thickness in the entire area of the display apparatus 100, the image quality is deteriorated due to light refraction at the interface of the encapsulation layer. When the encapsulation material is dispensed and spread in the entire area of the display apparatus 100, if the spreading speed is not uniform, the encapsulation material is not formed in the uniform thickness. For example, when the encapsulation material is spreading in all directions of the display apparatus 100, the encapsulation material is spreading at different speeds depending on the direction, so that a larger amount of the encapsulation material than the set amount is applied to certain areas and a smaller amount than the set amount to other areas. As a result, the cured encapsulating layer is formed in the non-uniform thickness.

The deterioration of the image quality occurs especially when the encapsulation layer is formed in the thickness less than the set thickness. Therefore, in order to form the entire encapsulation layer in the thickness greater than the set thickness in the general display apparatus, an amount of encapsulation material larger than the set amount should be dispensed, considering the difference in spreading speed. Further, a plurality of dams DAM must be formed in the non-display area to reliably block the encapsulation material exceeding the set amount from spreading to the outside.

In the present disclosure, since the spreading speed of the encapsulation material throughout the display apparatus 100 is uniform, it is possible to form the encapsulation layer of uniform thickness over the entire area of the display apparatus 100, even in the case of a relatively small amount of encapsulation material. In particular, in the present disclosure, since the encapsulating material is coated while observing the actual flow state of the encapsulating material spreading in the display apparatus 100, the encapsulating layer of uniform thickness can be formed with a relatively small amount of the encapsulating material. Therefore, the overflow of the encapsulation material to the outside of the display apparatus 100 can be prevented by only one dam DAM, thereby minimizing the area of the non-display area NA, for example, the area of the bezel.

In the present disclosure, a reflective member RRL can be disposed in one or more of the non-display area NA and the display area AA, without being limited thereto. As one example, the reflective member RRL can be disposed in the non-display area NA. For example, the reflective member RRL is disposed inside of the dam DAM in the non-display area NA, for example, region between the display area AA and the dam DAM to observe the spread of the encapsulation material inside. As will be described in detail later, the reflective member RRL indicates the presence or absence of the encapsulation layer due to the difference in luminance caused by the reflection of the external light in the area where the encapsulation layer is formed and the area where the encapsulation layer is not formed, without being limited thereto. Further, the location of the encapsulation layer can be determined by photographing the reflected light with a camera, or the operator can determine the location of the encapsulation layer by visually checking the reflected light.

In the drawing, the reflective member RRL is formed along the circumference of the display area AA in the non-display area NA. However, since the observation of the spreading speed of the encapsulating material is necessary in both the display area AA and the non-display area NA, the reflective member RRL can be formed in the display area AA and can be formed in the non-display area NA to the display area AA. Further, the reflective member RRL acts as a spreading path of the coated encapsulating material, so that the encapsulating material can be spreading at a uniform speed in the corresponding area.

As described above, in the present disclosure, by providing the reflective member RRL, the spreading speed of the encapsulating material can be uniform and the spreading state of the encapsulating material can be observed in real time, which will be described in more detail below.

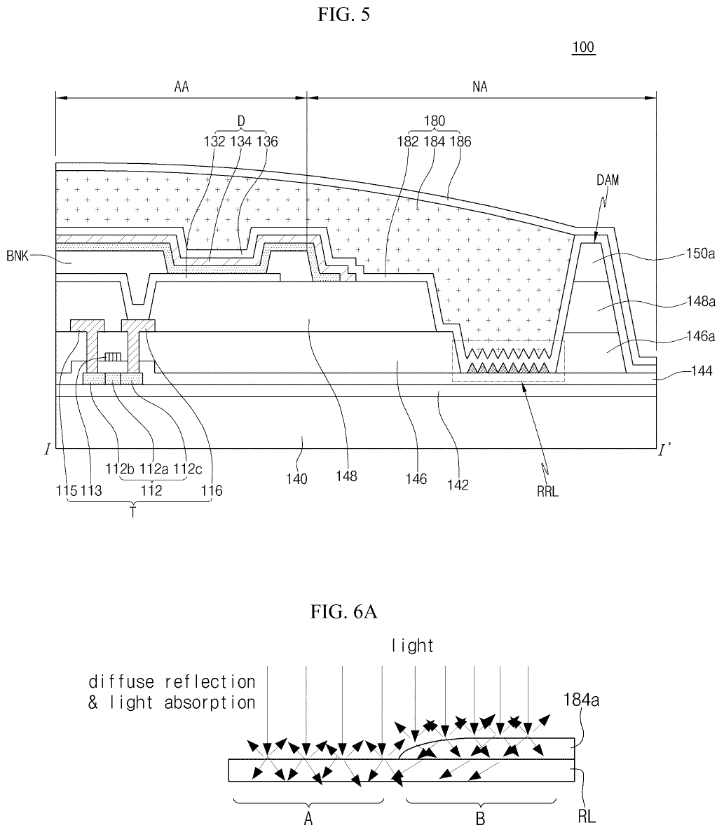

FIG. 5 is a cross-sectional view showing the structure of the sub-pixel of the display apparatus 100 according to the first example embodiment of the present disclosure, which is the cross-sectional view taken along line I-I′ of FIG. 4. At this time, the drawing shows the display area AA and the non-display area NA for convenience of explanation. In reality, a number of thin film transistors and various lines are arranged in the display area AA and the non-display area NA, but for convenience of explanation, the thin film transistors arranged in the display area AA are shown in the drawing.

As shown in FIG. 5, the substrate 140 includes the display area AA and the non-display area NA disposed outside the display area AA. For example, a plurality of transistors and light emitting device can be disposed in the display area AA. The substrate 140 can be made of a hard material such as glass or a flexible plastic-based material, without being limited thereto. Further, the substrate 140 can be made of a flexible polymer film.

In case where the substrate is made of the flexible polymer film, the substrate can be made of at least one material of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), but is not limited thereto.

In case where the substrate is made of the flexible plastic-based material, the substrate can be made of at least one material of a polyimide, a polymethylmethacrylate, a polyethylene tereththalate, a Polyethersulfone, and a Polycarbonate, but is not limited thereto.

When the substrate 140 is made of polyimide, the substrate 140 can be made of a plurality of polyimide layers, and an inorganic layer can be further disposed between the polyimide layers, but is not limited thereto.

The buffer layer 142 can be formed over the substrate 140 to enhance adhering force between the substrate 140 and the layers thereon. Further, the buffer layer 142 can block various types of defects, such as alkali components flowing out from the substrate 140. In addition, the buffer layer 142 can delay diffusion of moisture or oxygen penetrating into the substrate 140.

The buffer layer 142 can be a single layer made of silicon oxide (SiOx) or silicon nitride (SiNx), or multi-layers thereof. When the buffer layer 142 is made of multiple layers, SiOx and SiNx can be alternately formed. The buffer layer 142 can be omitted based on the type and material of the substrate 140, the structure and type of the thin film transistor, and the like.

A thin film transistor T is formed on the buffer layer 142 in the display area AA, without being limited thereto. In case where the buffer layer 142 is omitted, the thin film transistor T can be formed on the substrate 140 in the display area AA. For convenience of description, only the driving thin film transistor among various thin film transistors that can be disposed in the display area AA is illustrated, but other thin film transistors such as switching thin film transistors can also be included. In the figure, the thin film transistor of a top gate structure is shown, but the thin film transistor is not limited to this structure and can be formed in other structures such as the thin film transistor of a bottom gate structure.

The thin film transistor T can include a semiconductor pattern 112 disposed on the buffer layer 142, a gate insulating layer 144 covering the semiconductor pattern 112, a gate electrode 113 on the gate insulating layer 144, an interlayer insulating layer 146 covering the gate electrode 113, and a source electrode 115 and a drain electrode 116 on the interlayer insulating layer 146, without being limited thereto. Alternatively, in case where the buffer layer 142 is omitted, the semiconductor pattern 112 can be disposed on the substrate 140.

The semiconductor pattern 112 can be made of a polycrystalline semiconductor. For example, the polycrystalline semiconductor can be made of low temperature poly silicon (LTPS) having high mobility, but is not limited thereto.

The semiconductor pattern 112 can be made of an oxide semiconductor. For example, semiconductor pattern 112 can be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 can be formed in the display area AA and the non-display area NA or formed only in the display area AA, but is not limited thereto. The gate insulating layer 144 can be composed of a single layer or multiple layers made of an inorganic material such as SiOx or SiNx, but is not limited thereto.

The gate electrode 113 can be formed of a conductive material. For example, the gate electrode 113 can be made of a metal. For example, the gate electrode 113 can be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 can be made of the organic material such as photo-acryl, or the interlayer insulating layer 146 can be formed of the single layer or the multiple layers made of the inorganic material such as SiOx or SiNx, but is not limited thereto. Further, the interlayer insulating layer 146 can be formed of the multi layers of the organic material layer and the inorganic material layer, but is not limited thereto.

The source electrode 115 and the drain electrode 116 can be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 can be respectively contacted to the source region 112b and the drain region 112c of the semiconductor. For example, the source electrode 115 and the drain electrode 116 can be respectively contacted to the source region 112b and the drain region 112c of the semiconductor through contact holes formed in the gate insulating layer 144 and the interlayer insulating layer 146, but is not limited thereto.

A bottom shield metal layer can be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer can be composed of the single layer or the multi layers made of titanium (Ti), molybdenum (Mo), or an alloy thereof, but is not limited thereto.

A planarization layer 148 is formed on the substrate where the thin film transistor T is disposed. The planarization layer 148 can be configured to protect the thin film transistor T and to planarize a step caused due to the thin film transistor T. The planarization layer 148 can be formed of the organic material such as photoacrylic. But it is not limited thereto. The planarization layer 148 can include a plurality of layers including the inorganic layer and the organic layer.

A light emitting device D is disposed on the planarization layer 148 in the display area AA. The light emitting device D includes a first electrode 132, a light emitting layer 134, and a second electrode 136, but is not limited thereto. The first electrode 132 can be the anode electrode and the second electrode 136 can be the cathode electrode, but is not limited thereto.

The first electrode 132 is disposed on the planarization layer 148 and electrically connected to the drain electrode 116 of the thin film transistor T through the contact hole formed in the planarization layer 148. The first electrode 132 can be formed of at least one of silver (Ag), aluminum (Al), gold (Au), molybdenum (Mo), tungsten (W), chromium (Cr), or an alloy thereof, but is not limited thereto. Further, the first electrode 132 can be formed of a transparent metal oxide material such as indium tin oxide (ITO) or indium zinc oxide (IZO), but is not limited thereto.

When the display apparatus 100 is a top emission type display apparatus, the first electrode 132 can further include an opaque conductive material layer to function as a reflective electrode that reflects light, but is not limited thereto. When the display apparatus 100 is a bottom emission type display apparatus, the first electrode 132 can be made of the transparent conductive material such as ITO or IZO, but is not limited thereto.

A bank layer BNK is formed at the boundary between the sub-pixels on the planarization layer 148. The bank layer BNK can be a barrier wall to define sub-pixels. The bank layer BNK divides each sub-pixel to prevent light of a specific color output from adjacent pixels from being mixed and output. Further, the bank layer BNK can include a black dye in order to absorb light incident from the outside.

The bank layer BNK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

The light emitting layer 134 is formed on the upper surface of the first electrode 132, the inclined surface of the bank layer BNK, or the partial region of the upper surface of the bank layer BNK.

The light emitting layer 134 can be formed in plurality of sub-pixels. The light emitting layer 134 can be implemented to emit light of the same color such as white light for each pixel or to emit light of a different color such as red, green, or blue (e.g., white, red, green, or blue, or cyan, magenta, or yellow, etc.) for each pixel. For example, the light emitting layer 134 can be formed in the R, G, and B sub-pixels and can include an R-emitting layer for emitting red light, a G-emitting layer for emitting green light, and a B-emitting layer for emitting blue light. For example, the light emitting layer 134 can include an organic light emitting layer, an inorganic light emitting layer, a nano-sized material layer, a quantum dot layer, a micro LED light emitting layer, or a mini LED light emitting layer, but is not limited thereto.

The light emitting layer 134 can further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and can be formed of the single layer or the multi layers made of the metal or the alloy thereof, but is not limited thereto. Further, the second electrode 136 can be made of the transparent metal oxide material such as ITO or IZO, but is not limited thereto.

When the display apparatus 100 is the top emission type, the second electrode 136 can be made of the half-transparent conductive material that transmits light, but is not limited thereto. For example, the second electrode 136 can be made of at least one or more of the alloys such as LiF/Al, CsF/Al, Mg:Ag, Ca/Ag, Ca:Ag, LiF/Mg:Ag, LiF/Ca/Ag, or LiF/Ca:Ag, but is not limited thereto.

When the display apparatus 100 is the bottom emission type, the second electrode 136 can be the reflective electrode made of the opaque conductive material, but is not limited thereto. For example, the second electrode 188 can be made of at least one or more of silver (Ag), aluminum (Al), gold (Au), molybdenum (Mo), tungsten (W), chromium (Cr), or alloys thereof, but is not limited thereto.

Further, the light emitting device D can be formed in a tandem structure. The tandem structure can include a plurality of organic light emitting layers and a charge generating layer disposed between the organic light emitting layers. The charge generating layer is disposed to adjust the charge balance between the plurality of organic light emitting layers, and can be formed of a plurality of layers including a first charge generating layer and a second charge generating layer. The charge generating layer can include an N-type charge generating layer and a P-type charge generating layer. In this case, the charge generating layer can be formed of the organic layer doped with an alkali metal such as Li, Na, K, or Cs or an alkaline earth metal such as Mg, Sr, Ba, or Ra, but is not limited thereto.

An encapsulation layer 180 is formed in the display area AA and the non-display area NA to seal the light emitting device (D). When the light emitting device D is exposed to impurities such as moisture or oxygen, a pixel shrinkage phenomenon in which the light emitting area is reduced or the defect such as a dark spot in the light emitting area can occur. Further, moisture or oxygen penetrating into the light emitting device D oxidizes the metal electrode. The encapsulating layer 180 blocks impurities such as the oxygen and the moisture from the outside to prevent defects of the light emitting device D and various electrodes. When applying the encapsulation material to form an encapsulation layer, the dam DAM is formed in the non-display area NA to block the flow of the encapsulation material, thereby preventing the encapsulation material from flowing to the outside of the display apparatus 100.

The encapsulating layer 180 can be formed of a first encapsulating layer 182, a second encapsulating layer 184, and a third encapsulating layer 186, but is not limited thereto. For example, the first encapsulating layer 182 can be disposed on the substrate 140 on which the light emitting device D is disposed. The first encapsulation layer 182 and the third encapsulation layer 186 can extend from the display area AA to the end of the non-display area NA beyond the dam DAM, and the second encapsulation layer 184 can extend from the display area AA to the dam DAM in the non-display area NA, and is not formed in the outer area of the dam DAM, but is not limited thereto. The encapsulating layer 180 can be formed of two layers having organic layer and inorganic layer or four or more layers having organic layers and inorganic layers, but is not limited thereto.

The first encapsulating layer 182 and the third encapsulating layer 186 can be made of the inorganic material such as SiOx or SiNx, but are not limited thereto. The second encapsulating layer 184 can be made of the organic insulating material such as acrylic resin, epoxy resin, polyimide, polyethylene, or silicon oxycarbon (SiOC), but is not limited thereto. Further, the third encapsulation layer 186 can be made of thin metal (Face Seal Metal), but is not limited thereto.

A touch member can be disposed on the encapsulating layer 180. The touch member can detect external touch information using the user's finger or a touch pen. As one example, the touch member can comprise at least one touch sensor, and a touch sensing circuit capable of detecting the occurrence of a touch event by a touch object such as a finger, a pen, or the like, or detecting a corresponding touch location (or touch coordinates), by sensing the touch sensor, and the like.

A dam DAM is formed in the non-display area NA. The dam DAM is formed in the non-display area NA in a closed curve shape to surround the display area AA. When the insulating material having fluidity is coated to form the second encapsulation layer 184, the insulating material flowing out of the display apparatus 100 is blocked by the dam DAM. As shown in FIG. 5, the second encapsulation layer 184 can extend from the display area AA to the dam DAM in the non-display area NA, and is not formed in the outer area of the dam DAM.

The dam DAM can be made of various materials. As shown in FIG. 5, the dam DAM can be formed of three layers, without being limited thereto. For example, the dam DAM can include a first layer 146a, a second layer 148a, and a third layer 150a. For example, the second layer 148a can be disposed on the first layer 146a, and the third layer 150a can be disposed on the second layer 148a. At this time, the first layer 146a can be formed of the same material as the interlayer insulating layer 146 in the same process, and the second layer 148a can be formed of the same material as the planarization layer 148 in the same process, without being limited thereto. Further, the third layer 150a can be formed of the same material as the bank layer BNK in the same process, without being limited thereto.

Further, the dam can be formed of two layers. At this time, the first layer and the second layer can be formed of layers corresponding to the planarization layer 148 and the bank layer BNK, respectively, and the first layer and the second layer can be formed of layers corresponding to the interlayer insulating layer 146 and the bank layer BNK, respectively. Further, the first layer and the second layer can be formed of layers corresponding to the interlayer insulating layer 146 and the planarization layer 148, respectively. In addition, the dam DAM can be formed of layers made of the different material from the layer in the display area AA.

The first encapsulation layer 182 and the third encapsulation layer 186 of the encapsulation layer 180 can extend from the display area AA to the end of the non-display area NA beyond the dam DAM. For example, the first encapsulation layer 182 and the third encapsulation layer 186 can be formed on both sides and the top surface of the dam DAM. However, it is not limited to this, and the first encapsulation layer 182 and the third encapsulation layer 186 can be formed only up to the dam DAM. The second encapsulation layer 184 made of the organic material extends from the display area AA to the dam DAM in the non-display area NA, and is not formed in the outer area of the dam DAM. For example, second encapsulation layer 184 made of the organic material flowing out of the display apparatus 100 is blocked by the dam DAM.

A reflective member RRL can be disposed in the non-display area NA to observe the spread of the encapsulation material inside. When the organic material is coated to form the second encapsulation layer 184, the reflective member RRL indicates the location of the organic material over the reflective member RRL to the operator and then displays the coating process of the organic material in real time.

The reflective member RRL can be a retroreflective layer that reflects light incident from the outside in its original direction without diffuse or mirror reflection. The retroreflective layer is formed of a three-dimensional concavo-convex reflective layer, and thus the incident light is reflected by the reflective layer and then output along the incident path.

If the general reflective layer rather than the retroreflective layer is used as the reflective member RRL, the location of the encapsulation layer 180 cannot be determined. Hereinafter, the reason for forming the retroreflective layer as the reflective member RRL and the principle of determining the location of the encapsulation layer 180 by the retroreflective layer will be explained in detail.

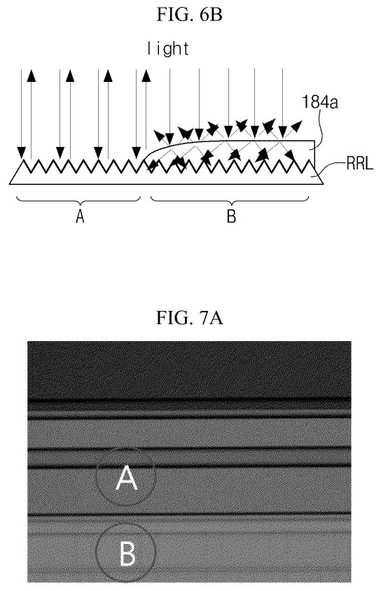

FIG. 6A is a view showing the location of the encapsulation layer 180 in case where the reflective member RL is the mirror-shaped reflective layer and FIG. 6B is a view showing the location of the encapsulation layer 180 in case where the reflective member RRL is the retroreflective layer according to the present disclosure. At this time, the figure illustrates determining the location of the second encapsulation layer 184 made of the organic material, but it is not limited thereto. Further, for convenience of explanation, in the figures, other components such as the substrate 140, the thin film transistor T, or the light emitting device D are omitted and only the reflective members RL and RRL and the second encapsulation layer 184 are shown.

As shown in FIG. 6A, when the organic material is dispensed on the substrate 140 on which the light emitting device D is disposed to form the second encapsulation layer 184, the organic material 184a is spread to the outside of the substrate 140 from the dispensed area. At this time, area A is an area where the organic material 184a is not coated, and area B is an area where the organic material 184a is coated.

When the reflective member RL is the mirror-shaped reflective layer, the light incident from the outside is reflected by the reflective member RL in areas A and B and is output. At this time, since the reflective member RL is the mirror-shaped reflective layer, the light reflected from the reflective member RL is diffusely reflected. Further, part of the light incident on area B is absorbed by the organic material 184a and part is refracted at the interface, and the light reflected and output from the reflective member RL is also absorbed by the organic material 184a and part is refracted at the interface.

In other words, as shown in FIG. 6A, the light incident from the outside is diffusely reflected on the surface of the reflective member RL and refracted at the interface of the organic material 184a, so that the light output from area A and area B is all mixed without directionality. Therefore, there is almost no difference in luminance between the light output from area A and area B, so that the boundary between area A and area B cannot be determined and thus the location of the organic material 184a cannot be determined.

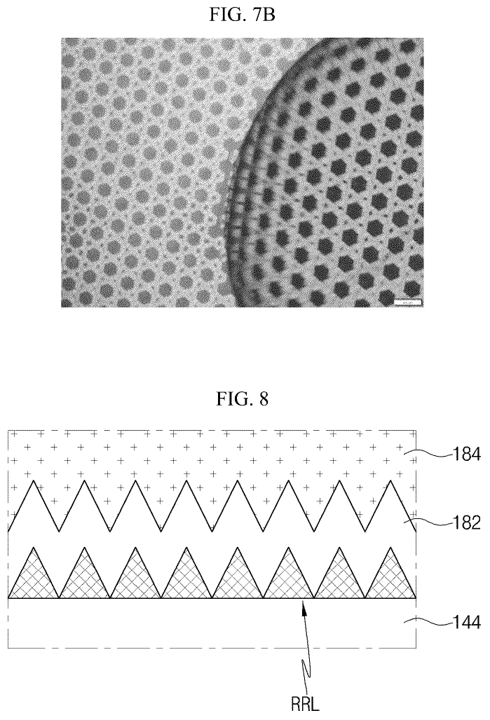

FIG. 7A shows an image of the light output when the reflective member RL is formed of the mirror-shaped reflective layer. FIG. 7B is a view showing the reflected image taken when the reflective member made of the retroreflective layer is formed.

As shown in FIG. 7A, in this case, there is almost no difference in luminance between area A and area B, so that the boundary between area A and area B cannot be determined and thus the location of the organic material 184a cannot be determined.

As shown in FIG. 6B, when the reflective member RRL is formed of the retroreflective layer, the light incident from the outside is reflected by the reflective member RRL in areas A and B and is output. At this time, since the reflective member RRL is the retroreflective layer, the light reflected from the reflective member RRL in area A is output as is along the original path.

On the other hand, a part of the light incident on area B is absorbed by the organic material 184a and other part is refracted at the interface, and a part of the light reflected and output from the reflective member RRL is also absorbed by the organic material 184a and other part is refracted at the interface.

In area A, since the incident light is output as is, the luminance of the output light is not decreased. On the other hand, in area B, since the light is absorbed and refracted by the organic material 184a, the luminance of the output light is much lower than the luminance of the incident light. Therefore, there is the luminance difference in the light output from area A and area B, so that the boundary between area A and area B can be determined and thus the location of the organic material 184a can be determined.

As shown in FIG. 7B, since the luminance of area B is lower than that of area A, the boundary between area A and area B is clearly visible, and thus the location of the organic material 184a forming the second encapsulation layer 184 can be identified. Therefore, it is possible to determine in real time whether the encapsulation layer 184 is a good product or a defective product.

For example, the reflective member RRL indicates the presence or absence of the organic material 184a due to the difference in luminance caused by the reflection of the external light in the area where the organic material 184a is formed and the area where the organic material 184a is not formed, without being limited thereto.

Meanwhile, the location of the organic material 184a can be determined by photographing the reflected light with a camera, or the operator can determine the location of the organic material 184a by visually checking the reflected light.

The reflective member RRL can be formed in various shapes. FIG. 8 is an enlarged cross-sectional view of the reflective member RRL of FIG. 5.

As shown in FIG. 8, the reflective member RRL can be made of a concave-convex metal layer. At this time, the metal layer can be made of the metal with good reflectivity. In particular, the metal layer can be made of the metal with getter properties. For example, the metal layer can be made of at least one material selected from the group consisting of Al, Mg, rare earth metals, and Ti, but is not limited thereto.

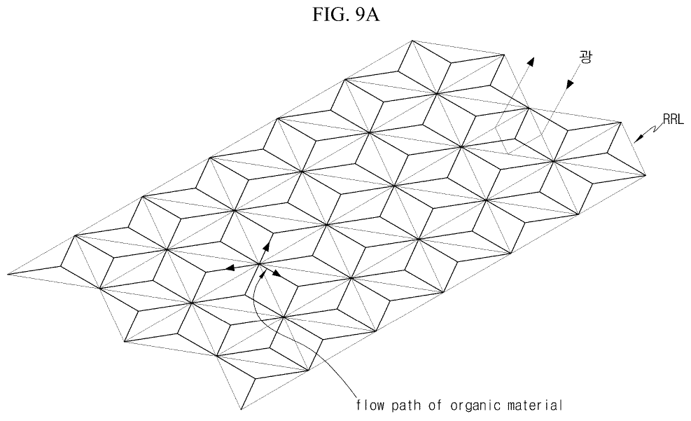

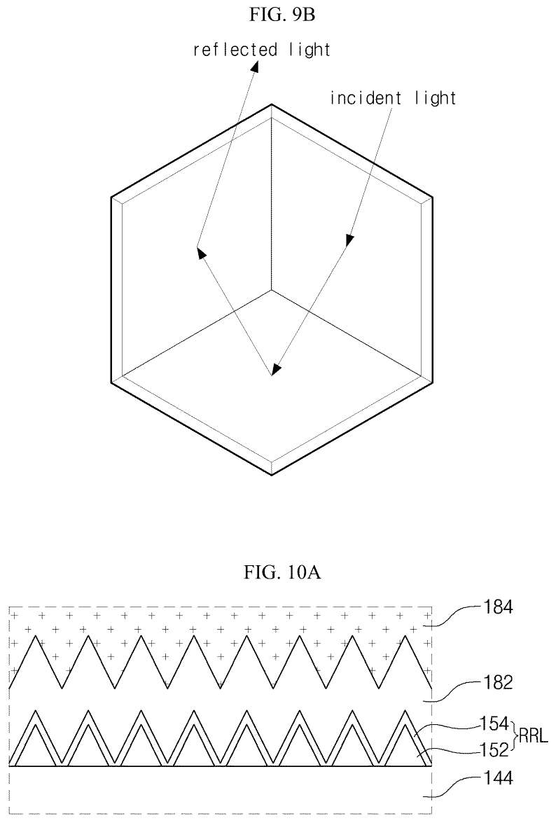

FIG. 9A is a view showing the specific structure of the reflecting member RRL formed of a plurality of corner reflectors according to the present disclosure and FIG. 9B is a view showing one corner reflector.

As shown in FIGS. 9A and 9B, the reflective member RRL of the display apparatus 100 according to the present disclosure can be formed of a plurality of corner reflectors, without being limited thereto. At this time, each corner reflector is constructed by combining three mirrors at an angle of 90 degrees in three dimensions. When the incident light goes through three consecutive reflections in the mirror, the final reflected direction is the same as the first incident direction. For example, the light reflected from the reflective member RRL is output as is along the original path.

However, the reflecting member (RRL) of the present disclosure is not limited to these corner reflectors. The reflective member RRL of the present disclosure can be formed of a plurality of semicircular mirrors that reflect incident light in the first incident direction, or can be formed of a plurality of glass beads whose surface where the light is reflected is coated with glass.

Meanwhile, the corners of the corner reflectors of the reflecting member RRL can form a flow path for organic materials. In other words, the corner reflector formed by three mirrors is formed in a concave, and when the spreading organic material 184a is filled into the inside of the concave shape and then overflows, the overflowing organic material 184a flows along the corner of the corner reflector into the concave of the adjacent corner reflector in the all directions. Further, the reflective member RRL acts as a spreading path of the organic material 184a, so that the organic material 184a can be spreading at a uniform speed in the corresponding area.

In this way, by forming the flow path of the organic material 184a at the corners of the corner reflector, the spread of the organic material 184a can be improved, so that the second encapsulation layer 184 of uniform thickness can be quickly formed.

As described above, the display apparatus according to the present disclosure can achieve the following effects by providing a reflective member RRL.

First, in the present disclosure, the reflective member RRL formed of the retroreflective layer is disposed in the non-display area NA to detect the light reflected from the reflective member RRL, so that the location of the organic material forming the second encapsulation layer 184 can be accurately determined. Therefore, it is possible to determine in real time whether the encapsulation layer 184 is a good product or a defective product.

Second, in the present disclosure, the corners of the plurality of corner reflectors of the reflecting member RRL form the path through which the organic material 184a spreads, so that the spreading speed of the organic material 184a can be uniform. Therefore, since the encapsulation layer of uniform thickness can be formed throughout the display apparatus 100 even with the relatively small amount of encapsulation material, the single dam DAM can prevent the encapsulation material from overflowing to the outside of the display apparatus 100, thereby minimizing the area of the non-display area NA, for example, the area of the bezel.

Third, in the present disclosure, the reflective member RRL made of the metal is disposed in the non-display area NA to block impurities such as moisture or oxygen penetrating from the outside, so that the defects caused by impurities can be prevented. Furthermore, in the present disclosure, since the reflective member RRL is made of the metal with getter properties, the penetration of moisture can be prevented more efficiently.

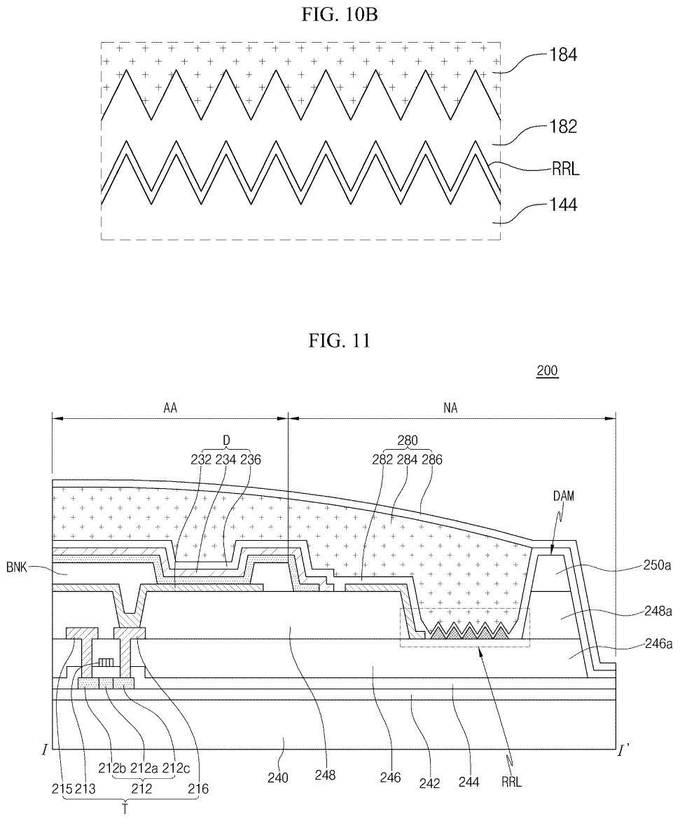

FIGS. 10A and 10B are enlarged cross-sectional views showing different structures of the reflective member RRL of the display apparatus 100 according to the first example embodiment of the present disclosure.

As shown in FIG. 10A, the reflective member RRL can be formed of two layers, and as shown in FIG. 10B, the reflective member RRL can be formed of one layer, without being limited thereto.

The reflective member RRL can be formed of a first layer 152 disposed on the gate insulating layer 144 and a second layer 154 formed on the first layer 152. At this time, the first layer 152 is a protruding layer made of the inorganic material or the organic material, and the plurality of layers form a three-dimensional concavo-convex shape. The second layer 154 can be a metal layer having the getter component such as Al, Mg, rare earth metal, or Ti formed on the first layer 152 to a predetermined thickness, without being limited thereto. As shown in FIG. 10A, the surface of the gate insulating layer 144 is flat, without being limited thereto.

As shown in FIG. 10B, the surface of the gate insulating layer 144 is etched into the three-dimensional concavo-convex shape, and the metal having the getter component such as Al, Mg, rare earth metal, and Ti is deposited thereon to form the reflective member RRL.

FIG. 11 is a cross-sectional view showing the display apparatus 200 according to a second example embodiment of the present disclosure. At this time, descriptions of the same structures as in FIG. 5 will be omitted or simplified, and only other structures will be described in detail.

As shown in FIG. 11, the thin film transistor T and the light emitting device D are disposed in the display area AA of the substrate 240, and the dam DAM is disposed in the non-display area (NA).

The thin film transistor T can include the semiconductor layer 212 disposed on the buffer layer 242, the gate electrode 214 disposed on the gate insulating layer 244, and the source electrode 215 and the drain electrode 216 disposed on the interlayer insulating layer 246. Further, buffer layer 242 can be omitted based on the type and material of the substrate, the structure and type of the thin film transistor, and the like.

The light emitting device D can include the first electrode 232, the light emitting layer 234, and the second electrode 236, but is not limited thereto. The first electrode 232 can be the anode electrode and the second electrode 236 can be the cathode electrode, but is not limited thereto.

The first electrode 232 can be made of at least one of silver (Ag), aluminum (Al), gold (Au), molybdenum (Mo), tungsten (W), chromium (Cr), or alloys thereof, but is not limited thereto. Further, the first electrode 232 can be made of the transparent metal oxide material layer, such as indium tin oxide (ITO) or indium zinc oxide (IZO), but is not limited thereto.

The second electrode 236 can be made of a translucent alloy such as LiF/Al, CsF/Al, Mg:Ag, Ca/Ag, Ca:Ag, LiF/Mg:Ag, LiF/Ca/Ag, and LiF/Ca:Ag, or the metal such as silver (Ag), aluminum (Al), gold (Au), molybdenum (Mo), tungsten (W), and chromium (Cr). Further, the second electrode 236 can be made of the transparent metal oxide that transmits light, such as ITO or IZO.

The encapsulation layer 280 is formed in the display area AA and the non-display area NA to seal the light emitting device (D). The encapsulation layer 280 including the first encapsulation layer 282 made of the inorganic material, the second encapsulation layer 284 made of the organic material, and the third encapsulation layer 236 made of the inorganic material is disposed over the light emitting device D, without being limited thereto. For example, the first encapsulation layer 282 can be disposed on the substrate 240 on which the light emitting device D is disposed.

A dam DAM is formed in the non-display area NA. The dam DAM can be formed of two layers. For example, the dam DAM is formed of the first layer 248a and the second layer 250a to prevent the organic materials from overflowing the display apparatus 200 when the second encapsulation layer 284 is formed. For example, the second layer 250a can be disposed on the first layer 248a. At this time, the first layer 248a can be made of the same material as the planarization layer 248 in the same process, and the second layer 250a can be made of the same material as the bank layer BNK in the same process, without being limited thereto.

The reflective member RRL can be formed in the non-display area NA along the perimeter of the display area AA. In particular, the reflective member RRL formed of the three-dimensional retroreflective layer is disposed inside the dam DAM in the non-display area NA, so that the flow of the organic material coated during the formation process of the second encapsulation layer 284 can be observed in real time to prevent over coating or under coating of organic material. Further, the reflective member RRL is formed of a three-dimensional protrusion shape so that the organic material is smoothly coated throughout the entire surface.

The reflective member RRL can be the concavo-convex metal layer formed on the planarization layer 248. At this time, the metal layer can be made of the metal with good reflectivity. At this time, the metal layer can be made of the metal having getter characteristics such as Al, Mg, rare earth metal, or Ti, but is not limited thereto.

As shown in FIGS. 10A and 11, the reflective member RRL can be formed of the protrusion formed on the interlayer insulating layer 246 and the metal layer formed on the protrusion. Further, as shown in FIGS. 10B and 11, the reflective member RRL can be made by etching the surface of the interlayer insulating layer 246 into the concavo-convex shape and forming the metal layer thereon.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments. Consequently, the scope of the present disclosure is defined by the accompanying claims and it is intended that all variations or modifications derived from the meaning, scope and equivalent concept of the claims fall within the scope of the present disclosure.

What is claimed is:

1. A display apparatus, comprising:
a substrate including a display area and a non-display area;
a plurality of transistors and a light emitting device disposed in the display area;
an encapsulation layer disposed in the display area and the non-display area; and
a reflective member disposed in the non-display area to surround the display area,
wherein the reflective member includes a retroreflective layer to reflect light incident from outside to observe flow of the encapsulating layer.

2. The display apparatus of claim 1, wherein each of the plurality of transistors includes:
a semiconductor layer on the substrate;
a gate insulating layer on the semiconductor layer;
a gate electrode on the gate insulating layer;
an interlayer insulating layer on the gate electrode; and
a source electrode and a drain electrode on the interlayer insulating layer.

3. The display apparatus of claim 2, wherein the reflective member includes a metal layer of a three dimensional concavo-convex shape on the gate insulating layer.

4. The display apparatus of claim 3, wherein a surface of the gate insulating layer is etched in the three dimensional protrusion shape, and the reflective member is the metal layer disposed on the surface of the gate insulating layer.

5. The display apparatus of claim 2, wherein the reflective member includes:
a plurality of protruding insulating layers disposed on the gate insulating layer; and
a metal layer disposed on the plurality of protruding insulating layers.

6. The display apparatus of claim 2, wherein the reflective member is a metal layer of a three dimensional concavo-convex shape on the interlayer insulating layer.

7. The display apparatus of claim 6, wherein a surface of the interlayer insulating layer is etched in the three dimensional protruding shape, and the reflective member is the metal layer disposed on the surface of the interlayer insulating layer.

8. The display apparatus of claim 2, wherein the reflective member includes:
a plurality of protruding insulating layers disposed on the interlayer insulating layer; and
a metal layer disposed on the plurality of protruding insulating layers.

9. The display apparatus of claim 3, wherein the metal layer is disposed of the metal have getter characteristics.

10. The display apparatus of claim 9, wherein the metal layer includes at least one material among Al, Mg, rare earth metals, and Ti.

11. The display apparatus of claim 2, further comprising a dam disposed in the non-display area.

12. The display apparatus of claim 11, wherein the reflective member is disposed between the display area and the dam.

13. The display apparatus of claim 11, wherein the dam comprises:
a first layer disposed on the gate insulating layer;
a second layer disposed on the first layer; and
a third layer disposed on the second layer.

14. The display apparatus of claim 11, wherein the dam comprises:
a first layer disposed on the interlayer insulating layer; and
a second layer disposed on the first layer.

15. The display apparatus of claim 12, wherein the reflective member is extended to the display area.

16. The display apparatus of claim 11, wherein the reflective member includes a plurality of corner reflectors disposed by combining three mirrors at an angle of 90 degrees in three dimensions.

17. A display apparatus, comprising:
a substrate including a display area and a non-display area;
a plurality of transistors and a light emitting device disposed in the display area;
an encapsulation layer disposed in the display area and the non-display area; and
a reflective member disposed in the non-display area to surround the display area,
wherein the reflective member includes a plurality of corner reflectors disposed by combining three mirrors at an angle of 90 degrees in three dimensions.

18. The display apparatus of claim 17, wherein each of the plurality of transistors includes:
a semiconductor layer on the substrate;
a gate insulating layer on the semiconductor layer;
a gate electrode on the gate insulating layer;
an interlayer insulating layer on the gate electrode; and
a source electrode and a drain electrode on the interlayer insulating layer.
